(19) United States
(12) Patent Application Publication
(10) Pub. No.: US 2012/0307460 A1
(43) Pub. Date: Dec. 6, 2012

(54) PUSHBUTTON MEMBER FOR ELECTRONIC MODULE

(76) Inventor: Glenn C. Simon, Auburn, CA (US)

(21) Appl. No.: 13/149,772

(22) Filed: May 31, 2011

(51) Int. Cl. H05K 7/00

(52) U.S. Cl. 361/747

(57) ABSTRACT

An apparatus includes a pushbutton member; a receiving member movable by the pushbutton member; and a latching member affixed to an electronic module and latchable to the receiving member. When the latching member is latched, the electronic module is movable via the receiving member. Alternatively, an apparatus is provided including a pushbutton members and a receiving section having a protruding receiving member, and movable by the pushbutton members. The receiving member may receive a latching member affixed to an electronic module. When the latching member is latched, the electronic module is movable via the receiving member. Alternatively, an apparatus includes an electronic module; and a latching member affixed to the electronic module, the latching member to latch to a receiving member. When the latching member is latched to the receiving member, the electronic module is movable via the receiving member in a direction of movement of the receiving member.

### BACKGROUND OF THE INVENTION

In the electronics industry, which may include, among other things, server, storage and networking products, the space on the front and rear surfaces of a product is highly valuable. The front and rear surfaces of a product are generally the only surfaces of the product with which the customer can interact. Many devices, components, etc., may be placed on the front and rear surfaces of the product, for example, connectors, labels, light-emitting diodes (LED's), displays, fans, vents, power supplies, removable modules, etc. As such, providing a large space for insertion/ejection mechanisms may take away available space for beneficial devices, components, etc., that may otherwise be placed on the front and rear surfaces.

Removable electronic modules may be highly valuable from a product feature perspective and may require an EMI seal to prevent electromagnetic noise emission from the product. They often require a large connector to interface and communicate with the system to which they are connected. Both the connector and electromagnetic interference (EMI) seal typically result in high insertion and extraction forces, thus making insertion and removal of these types of devices difficult.

### DRAWINGS

FIG. 1 is a left side perspective view of an example of an electronic module latched to a pushbutton mechanism in a chassis, according to at least one embodiment of the present disclosure;

FIG. 2 is a left side perspective view of an example of an electronic module to engage a pushbutton mechanism, according to at least one embodiment of the present disclosure;

FIG. 3 is a left side view of an example of an a latch to be latched to a receiving member, according to at least one embodiment of the present disclosure;

FIG. 4 is a left side view of an example of a latch engaging with a displacement member, according to at least one embodiment of the present disclosure;

FIG. 5 is a left side view of an example of a latching member engaged with a receiving member, according at least one embodiment of the present disclosure;

FIG. 6 is a left side perspective view of pushbutton mechanism, according to at least one embodiment of the present disclosure;

FIG. 7 is a right side perspective view of an example of a pushbutton mechanism, according to at least one embodiment of the present disclosure;

FIG. 8 is a right side perspective view of an example of a pushbutton mechanism, according to at least one embodiment of the present disclosure;

FIG. 9 is a right side perspective view of an example of a pushbutton mechanism, according to at least one embodiment of the present disclosure;

FIG. 10 is a right side perspective view of an example of a pushbutton mechanism, according to at least one embodiment of the present disclosure;

FIG. 11 is a left side perspective view of an example of a pushbutton mechanism, according to at least one embodiment of the present disclosure;

FIG. 12 is a left side perspective view of an example of a pushbutton mechanism without extraction button, according to at least one embodiment of the present disclosure;

FIG. 13 is a right side perspective view of an example of a pushbutton mechanism, according to at least one embodiment of the present disclosure;

FIG. 14 is a right side perspective view of an example of a pushbutton mechanism, according to at least one embodiment of the present disclosure;

FIG. 15 is a right side perspective view of an example of a pushbutton mechanism, according to at least one embodiment of the present disclosure;

FIG. 16 is a right side perspective view of an example of a pushbutton mechanism, according to at least one embodiment of the present disclosure;

FIG. 17 is a left side perspective view of an example of a pushbutton mechanism, according to at least one embodiment of the present disclosure.

FIG. 18 is a right side perspective view of an example of a pushbutton mechanism, according to at least one embodiment of the present disclosure; and

FIG. 19 is a left side perspective view of an example of a pushbutton mechanism, according to at least one embodiment of the present disclosure.

### DETAILED DESCRIPTION

A pushbutton mechanism is provided that enables an electronic module to be inserted and extracted from a chassis. The pushbutton mechanism may be attached to a chassis and may interact with a latching member at an electronic module. The pushbutton mechanism may also be attached to the module and may interact with a latching member at the chassis. In order to insert the electronic module into the chassis, the electronic module may be partially inserted into the chassis to such a point where a latching member on the electronic module engages a receiving member attached to the pushbutton mechanism attached to the chassis. Once engaged, the insertion button may be pushed thereby moving the receiving member toward the inside of the chassis. As the latching member of the electronic module is engaged with the receiving member, the electronic module moves toward the inside of the chassis. Upon full depression of the insertion button, electronic components having connectors on the electronic module may engage with connectors located inside, for example, on a backplane of, the chassis.

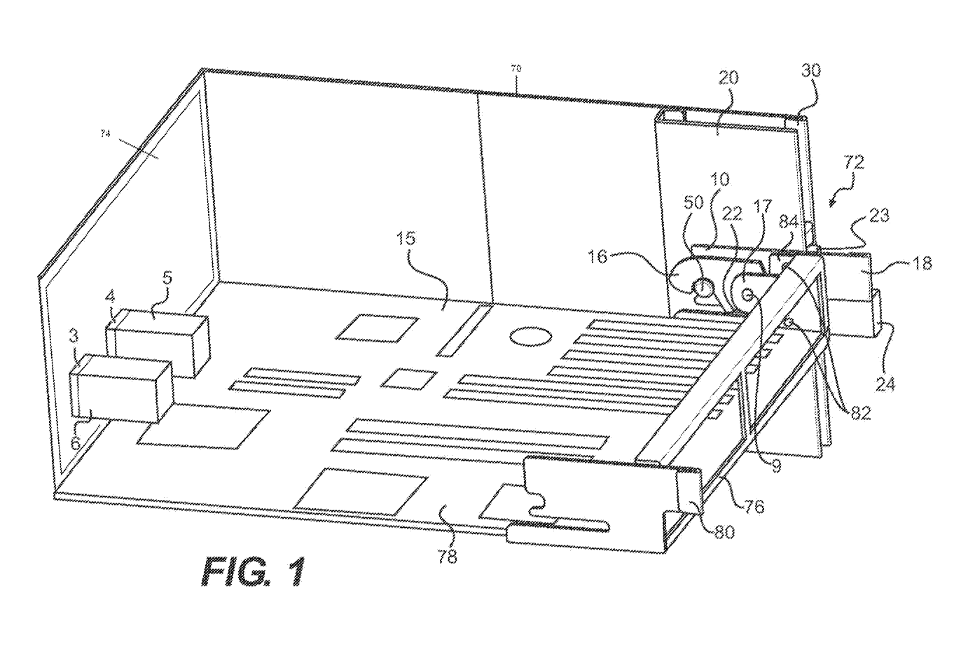

FIGS. 1-5 describe the operation of the latching member and the pushbutton mechanism as the electronic module is inserted into the chassis 70 to a point where the latching member 16 is engaged with the pushbutton mechanism.

FIG. 1 depicts an electronic module 15 latched to a pushbutton mechanism 72, the pushbutton mechanism 72 attached to a chassis 70. As shown in FIG. 1, the electronic module 15 is in a state where it is inserted into the chassis 70 via the pushbutton mechanism 72 where connectors 5, 6 are engaged with corresponding connectors 3, 4 at, for example, a backplane 74 at a rear wall in the chassis 70. Electronic module 15 may include a printed circuit board (PCB) 78 and a faceplate 76 through which components on the PCB maybe accessed once the electronic module 15 is inserted into the chassis 70. Attached to the faceplate 76 and the PCB 78 are handles 18, 80. Handles 18, 80 may facilitate insertion or extraction of the electronic module 15 into and out of the chassis 70.

Handle 18 may be a portion of plate 10. Plate 10 may be affixed to the PCB 78 via a side portion 84 of faceplate 76 at connection points 82. These connection points may be screws, rivets, welds, etc., or any other type connection that may firmly affix plate 10 to side portion 84. Plate 10 may further have movably affixed thereto a latching member 16. Latching member 16 may be movable in a direction orthogonal to the PCB 78 in that the latching member 16 pivots about a pivot point 9 where the latching member 16 is connected to a side portion of faceplate 17.

Pushbutton mechanism 72 may include pushbutton members, for example, an insertion button 24 and an extraction button 23. Pushbutton mechanism 72 may further include cover 20 to protect the movable components of pushbutton mechanism 72. Pushbutton mechanism 72 may be connected to chassis 70, at least in part, at chassis side wall portion 30. Receiving member 50 may protrude through cover 20 at a hole (not shown in FIG. 1). Receiving member 50 may be movable via insertion button 24 and extraction button 23. Latching member 16 of the electronic module 15 may engage with receiving member 50 wherein electronic module 15 is movable via insertion button 24, extraction button 23 and receiving member 50 as will be more fully discussed below.

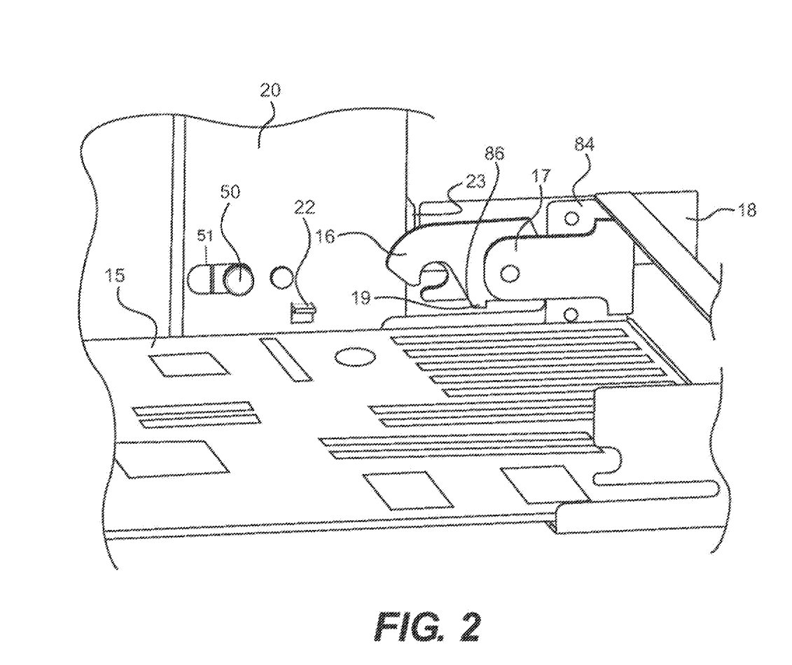

FIG. 2 depicts a side perspective view of an example of an electronic module in a state of insertion, where the electronic module is about to engage the pushbutton mechanism. As can be more clearly seen in FIG. 2, latching member 16 has a hook-like shape, the member having a slanted portion 86 extending to protrusion 19.

Pushbutton mechanism 72 includes cover 20 having an oval hole 51 through which receiving member 50 protrudes.

Displacement member 22 is a rigid member that protrudes orthogonally to cover 20. Displacement member 22 interacts with protrusion 19 during removal of the module to disengage the latching member 16 from the receiving member 50.

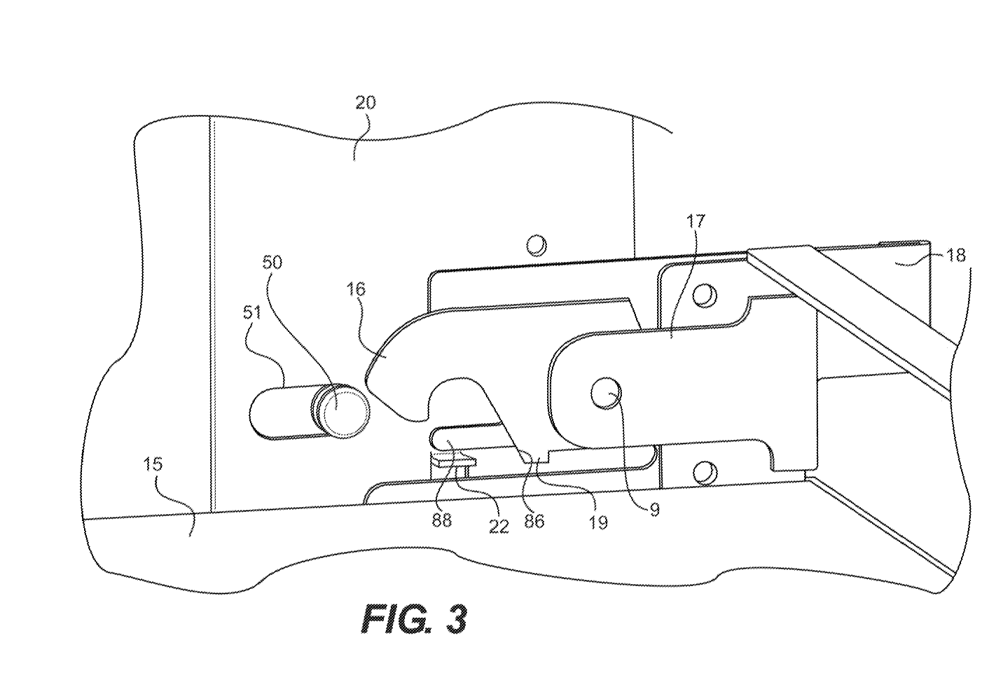

FIG. 3 depicts a side view of an example of an electronic module 15 being inserted into the chassis 70. In FIG. 3, latching member 16 is about to engage receiving member 50 at an angled edge of latching member 16. As noted above, receiving member 50 may protrude through a hole 51 in cover 20.

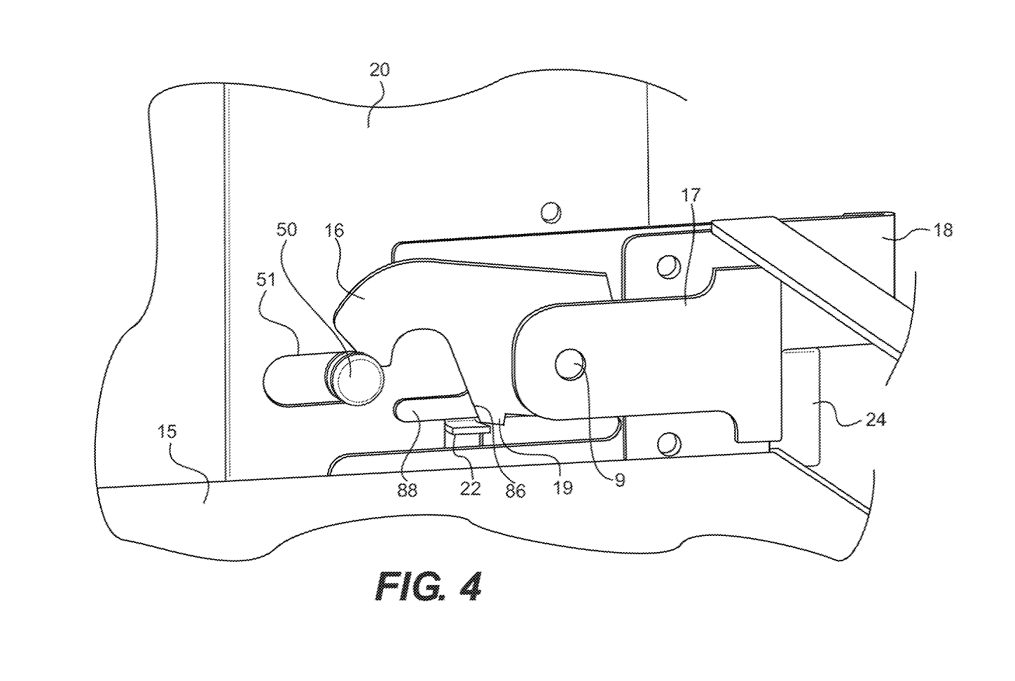

FIG. 4 is a side view of an example of an electronic module 15 being inserted into the chassis 70 wherein the angled edge of 16 a latching member 16 at the electronic module 15 is engaging receiving member 50 at pushbutton mechanism 72. When latching member 16 engages with receiving member 50, the movement of the electronic module 15 into the chassis 70 enables the latching member 16 to rotate upward about pivot 9.

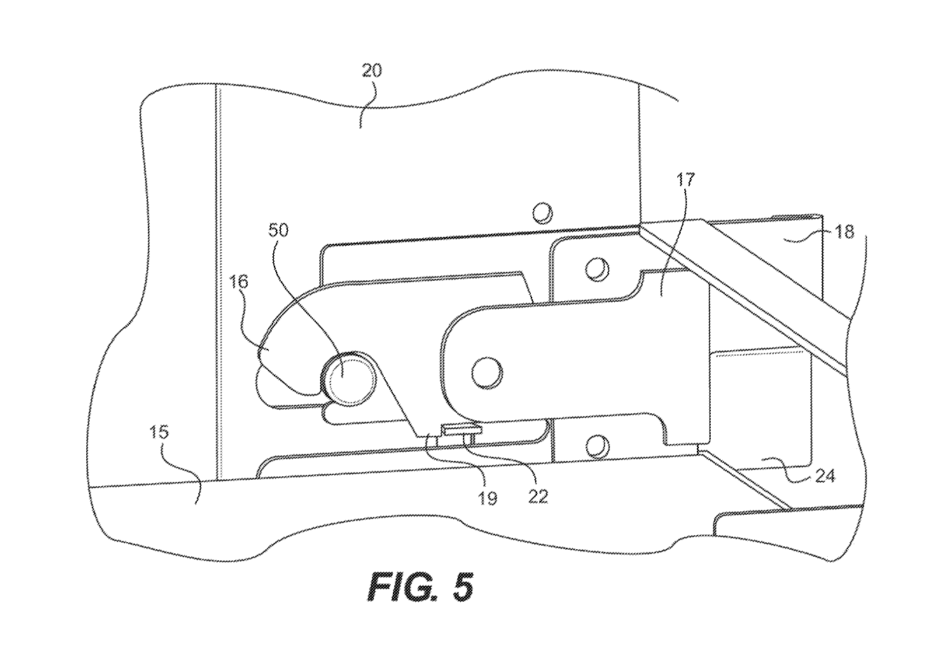

FIG. 5 is a side view of an example of the electronic module 15 being inserted into the chassis 70 wherein the electronic module 15 has been inserted into the chassis sufficiently so that the latching member 16 has latched about receiving member 50. In addition, the electronic module has been inserted sufficiently so that the protrusion of the latching member 19 has reached a point past the displacement member 22. Upon the latching member engaging about the receiving member 50, the latching member, due to a spring located between member 17 and handle 18 or, for example, gravity, falls in a downward direction, rotating about pivot 9. Upon falling in a downward direction, the protrusion of the latching member 19 falls past the displacement member, thereby effectively locking the latching member 16 onto the receiving member 50.

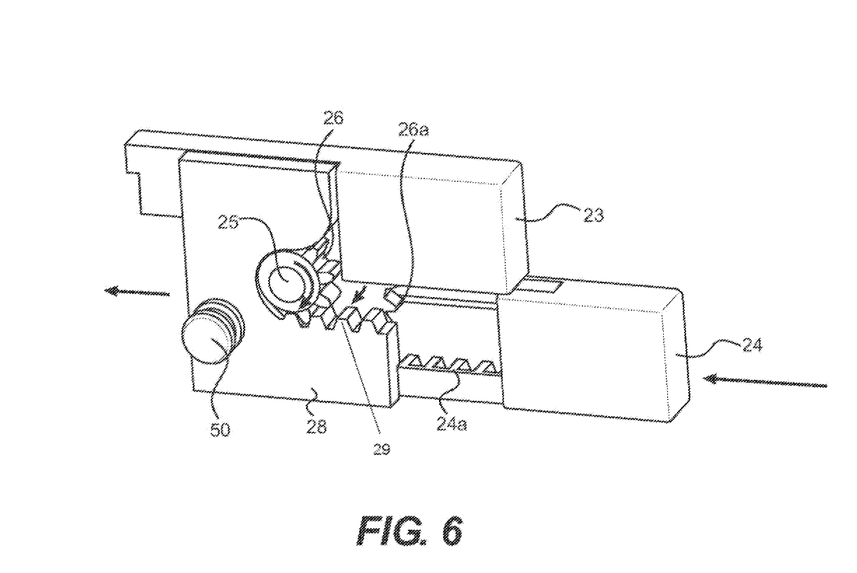

FIG. 6 is a side perspective view of pushbutton mechanism. The components depicted in FIG. 6 may be configured between cover 20 and chassis side wall portion 30. Pushbutton mechanism may include insertion button 24 and extraction button 23. The pushbutton mechanism depicted in FIG. 6 is in a state where the insertion button 24 is to be pushed to insert an electronic module 15 into the chassis 70.

Insertion button 24 includes a rack portion 24a. Rack portion 24a is configured to abut against receiving section 28. Receiving section 28 includes a rack portion 29 and receiving member 50. Rack portion 29 of receiving section 28 is configured to engage pinion portion 25 at a pinion 26. Pinion portion 25 has a pinion 26a that is configured to engage rack portion 24a of insertion button 24. As pinion 26 is configured to be smaller than pinion 26a, and, as the two gears are working in tandem, a mechanical advantage may be achieved resulting in less force, for example, ⅓ less force, required to insert the module into the chassis than if the pushbutton mechanism described herein were not implemented.

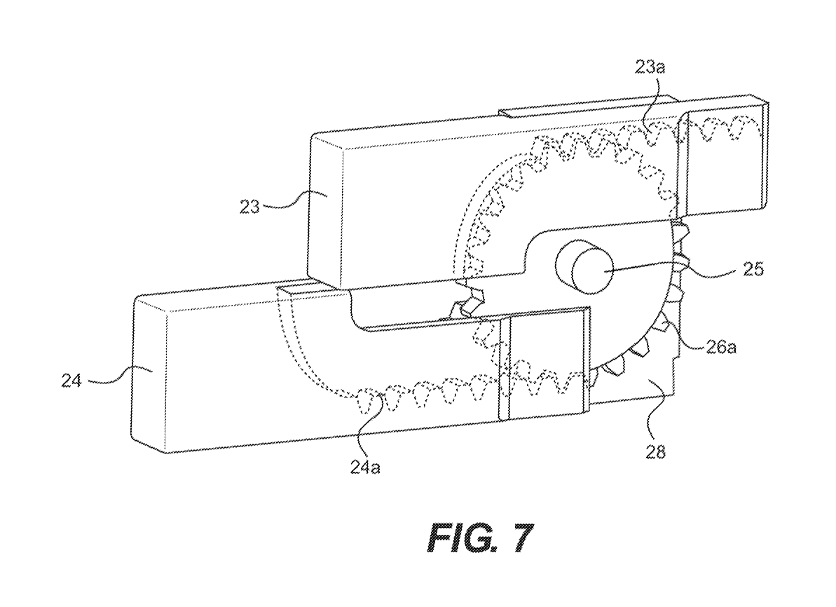

FIG. 7 is a side perspective view of an example of a pushbutton mechanism in the same state of the pushbutton mechanism as depicted in FIG. 6. As can been seen in FIG. 7, pinion 26a is further engagable with a rack portion 23a of extraction button 23.

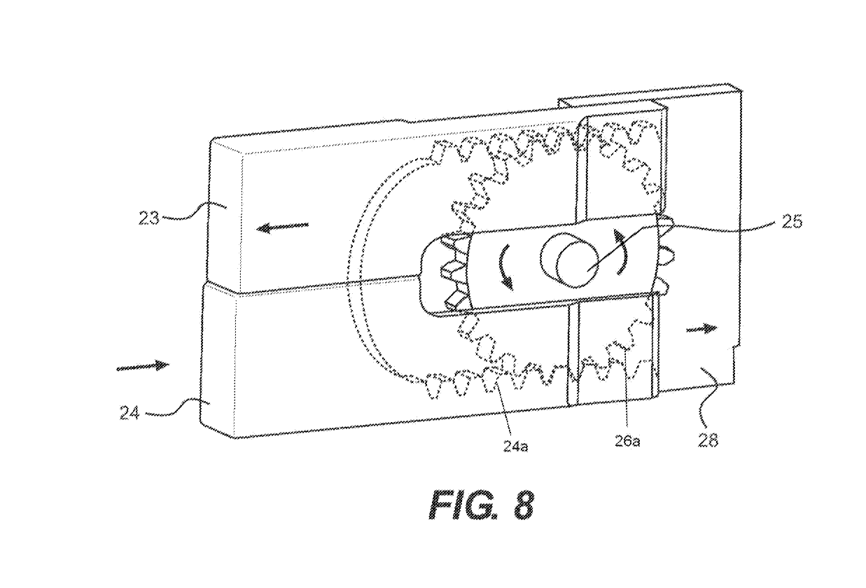

FIG. 8 is a side perspective view of an example of a pushbutton mechanism where insertion button 24 has been engaged and is half depressed. As can be seen in FIG. 8, upon actuation of insertion button 24, rack portion 24a engages pinion portion 25 at second pinion 26a to rotate pinion portion 25. Rotation of pinion portion 25 results in rotation of pinion 26 (FIG. 6) at pinion portion 25. Pinion 26 engages rack portion 29 of receiving section 28 (FIG. 6) thereby moving receiving section 28 in a direction inward into the chassis 70. As the electronic module is attached to receiving member 50 of receiving section 28 via latching member 16, the electronic module moves with the receiving section 28 into the chassis 70.

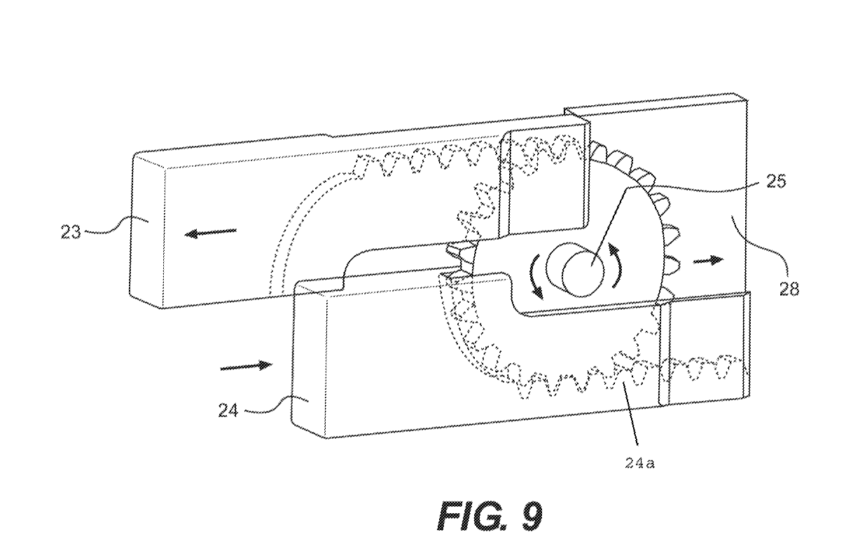

FIG. 9 is a side perspective view of an example of a pushbutton mechanism where insertion button 24 has been engaged and is fully depressed. As can be seen in FIG. 9, upon full actuation of insertion button 24, rack portion 24a continues to engage pinion portion 25 at second pinion 26a to rotate pinion portion 25. Rotation of pinion portion 25 continues to rotate pinion 26 at pinion portion 25 (FIG. 6). Pinion 26 engages rack portion 29 of receiving section 28 and moves receiving section 28 completely into the chassis 70. At this point, connectors 5, 6 of electronic components mounted to electronic module 15 engage and are pushed into corresponding connectors 3, 4 at, for example, a backplane 74 on the back wall of the chassis 70 (FIG. 1).

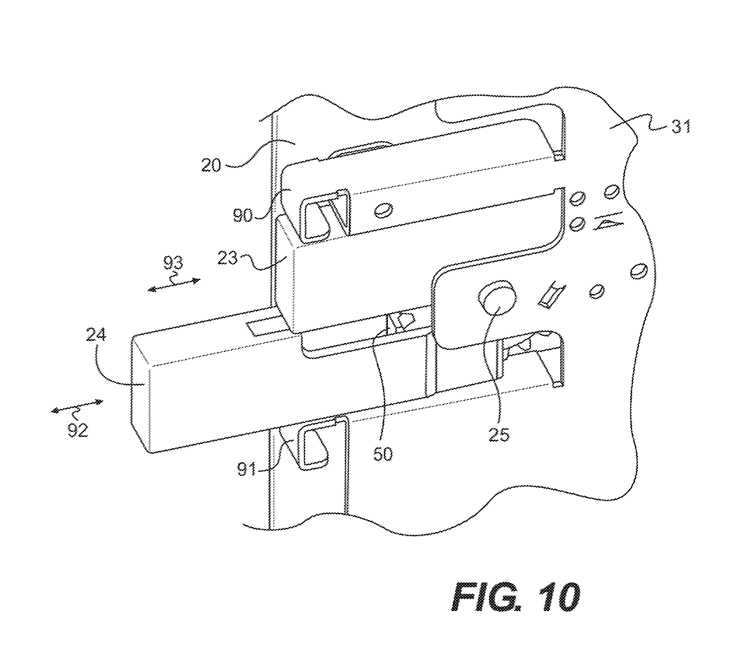

FIG. 10 is a side perspective view of an example of a pushbutton mechanism mounted to a side wall 30 of chassis 70. Insertion button 24 and extraction button 23 may be configured between button retainers 90 and 91 wherein insertion button 24 and extraction button 23 are movable in a direction identified by arrows 92, 93, respectively.

Extraction of the electronic module may be achieved upon execution of the extraction button 23. Extraction button may protrude from the pushbutton extraction mechanism 72 when the insertion button 24 is activated. Upon activation of the extraction button, rack portion 23a engages pinion 26a. Pinion 26a rotates in a direction opposition to the direction of rotation during insertion. Rotation of pinion 26a results in rotation of pinion 26. Pinion 26 engages rack portion 29 of receiving section 28 and moves receiving section in a direction opposite to the direction of movement during actuation of the insertion button 24. Movement of the receiving section 28 results in movement of receiving member 50. As receiving member 50 moves outward, it pushes on an edge the handle 18, and no longer contacts the hook portion of member 16. When button 23 is fully depressed, receiving member 50 is positioned in its forward-most position, and 19 and 22 are in contact (FIG. 5). When the module is removed by pulling on handles 18 and 80 (FIG. 1), the interaction between 19 and 22 cause the latching member 16 to rotate upward rapidly, disengaging it from receiving member 50 and freeing the module for removal.

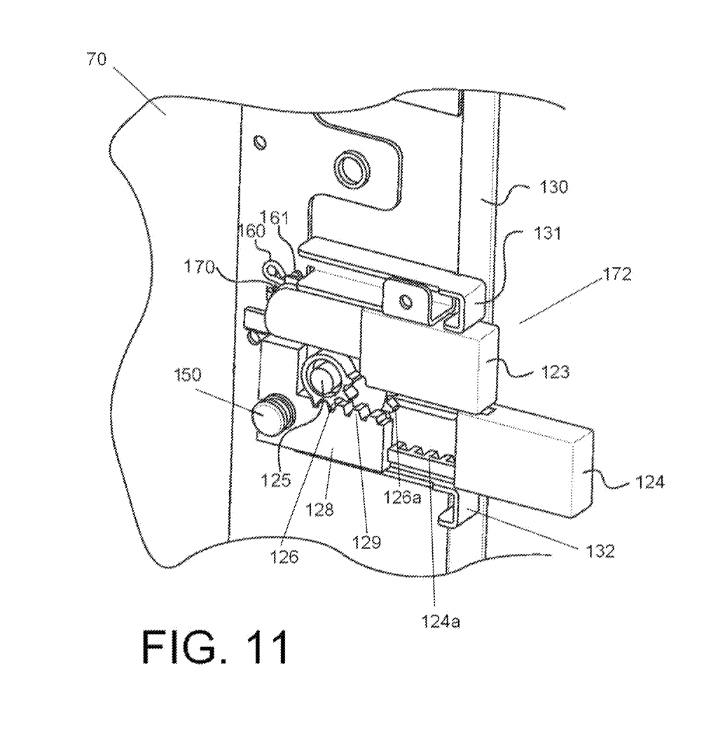

FIGS. 11-19 describe an alternative embodiment of a pushbutton mechanism. The pushbutton mechanism described in FIGS. 11-19 provide for functionality where the insertion and extraction buttons do not extend beyond the front surface of the chassis when they are in a stored position within the pushbutton mechanism.

The latching member 16, the chassis 70, cover 20 and the electronic module 15 as described in FIGS. 1-10 may be implemented with the pushbutton mechanism described in FIGS. 11-20.

The pushbutton mechanism of FIG. 11 is in a state where the insertion button is to be pushed to insert an electronic module 15 into the chassis 70.

As can be seen in FIG. 11 pushbutton mechanism may include pushbutton members, for example insertion button 124 and extraction button 123. Insertion button 124 may have rack portion 124a. Pushbutton mechanism 172 may further include a cover 20 (not shown in FIG. 11) configured as described in FIGS. 1-10 to protect the movable components of pushbutton mechanism 172. Pushbutton mechanism 172 may be connected to chassis 70, at least in part, at chassis side wall portion 30. Receiving member 150 may protrude through cover 20 at a hole 51 described in FIGS. 1-10. Receiving member 150 may be movable via insertion button 124 and extraction button 123. Latching member 16 of the electronic module 15 described in FIGS. 1-10 may engage with receiving member 150 wherein electronic module 15 is movable via insertion button 124, extraction button 123 and receiving member 150 as will be more fully discussed below.

Insertion button 124 includes a rack portion 124a. Rack portion 124a is configured to abut against receiving section 128. Receiving section 128 includes a rack portion 129 and receiving member 150. Rack portion 129 of receiving section 128 is configured to engage gear portion 125 at a pinion 126. Gear portion 125 has a pinion 126a that is configured to engage rack portion 124a of insertion button 124.

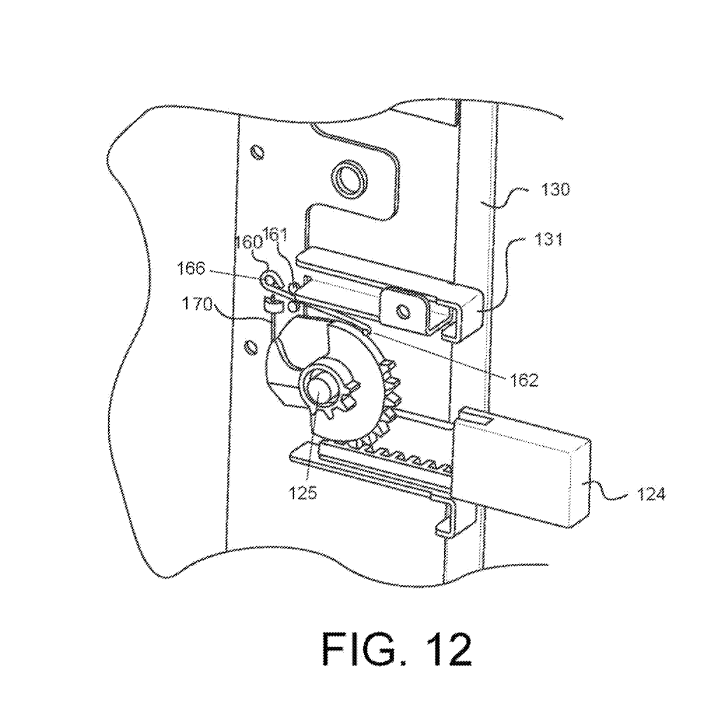

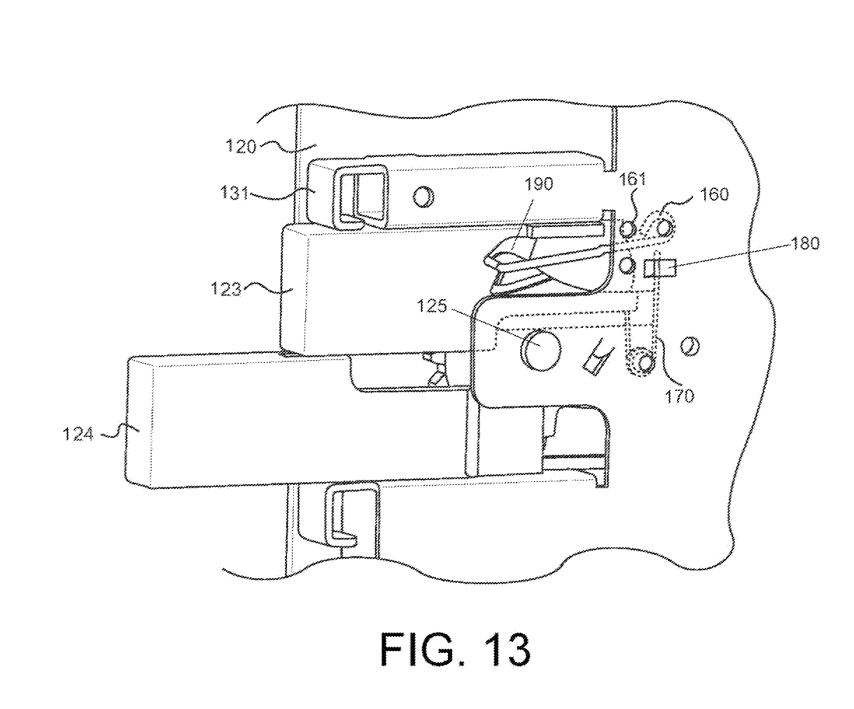

FIG. 12 is a side perspective view of an example of the pushbutton mechanism without extraction button 123 depicted. Pushbutton mechanism 172 further includes a track follower 160 which pivots about pin 166 and is constrained to move in a range by retainers 161 to follow a track portion 190 in pushbutton 123 (FIG. 13). Track follower 160, at hook portion 162, follows track portion 190 in pushbutton 123 as the pushbutton is pressed and released as described below.

FIG. 13 is a side perspective view of an example of the pushbutton mechanism. Pushbutton mechanism further includes spring 170. Spring 170 may be implemented as a torsion spring where one arm is affixed at one end to the chassis wall at 180. The other end of the spring may engage with extraction button 123.

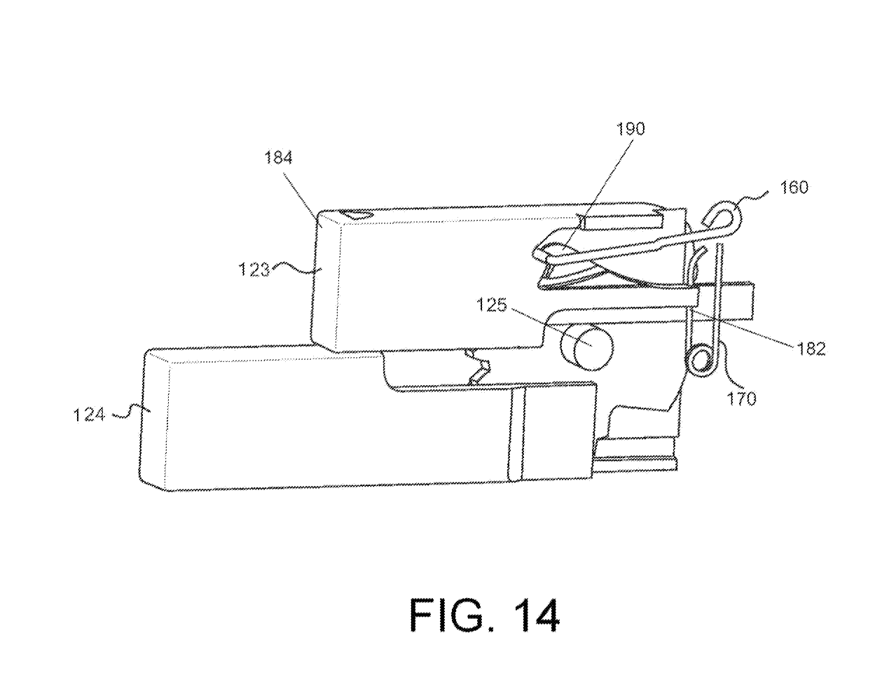

FIG. 14 is a side perspective view of an example of the pushbutton mechanism as shown in FIG. 13 without the chassis wall or the cover 20. As can be seen in FIG. 14, the free end of spring 170 engages with the extraction button 123 at 182. Spring 170 exerts a force on extraction button 123 in a direction out of the pushbutton mechanism at the front of the chassis 70. Extraction button 123 is retained in its position via track follower 160 at hook portion 162, which engages with track portion 190 of extraction button 123.

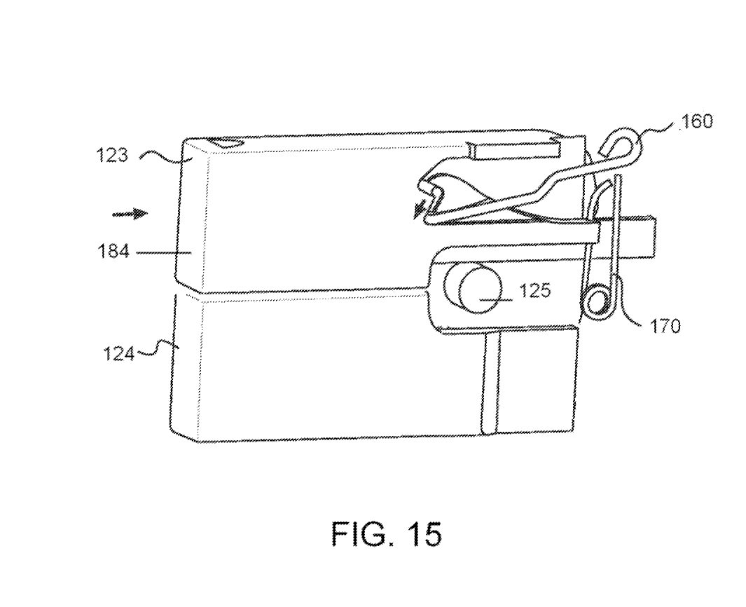

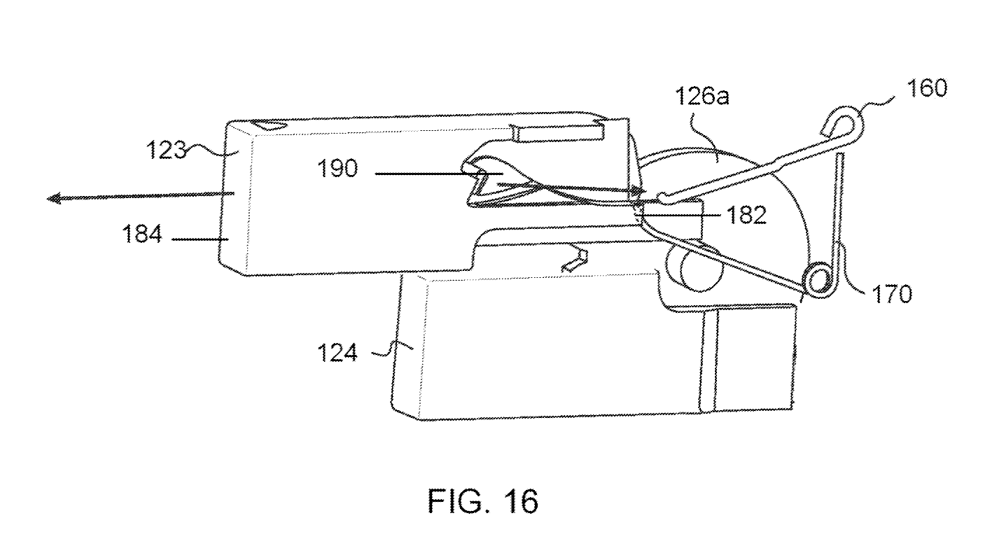

FIG. 15 is a side perspective view of an example of the pushbutton mechanism as shown in FIG. 14 where the tip 184 of the extraction button 123 has been pushed inward and the extraction button 123 has been pushed into the pushbutton mechanism 172. As can be seen in FIG. 15, the track follower 160 follows a groove in the track which forces the track follower 160 downward in the direction of the arrow. The track follower 160 can only go in this direction, because of a step in the bottom of the groove which only allows the hook portion of the track follower 160 to travel in one direction through the track. When the track follower is in the position shown in FIG. 15, it drops over a second step at the bottom of the groove of the track, which prevents the track follower 160 from returning to its previous position. Upon release of the force at the tip 184 of extraction button 123, spring 170 decompresses thereby exerting a force at 182 (FIG. 16) pushing the extraction button 123 in a direction of the arrow in FIG. 16 out the front of the pushbutton mechanism 172. Track follower 160 slides in track portion 190 as extraction button 123 moves in the direction of the arrow and the track follower 160 is released from interaction with track portion 190.

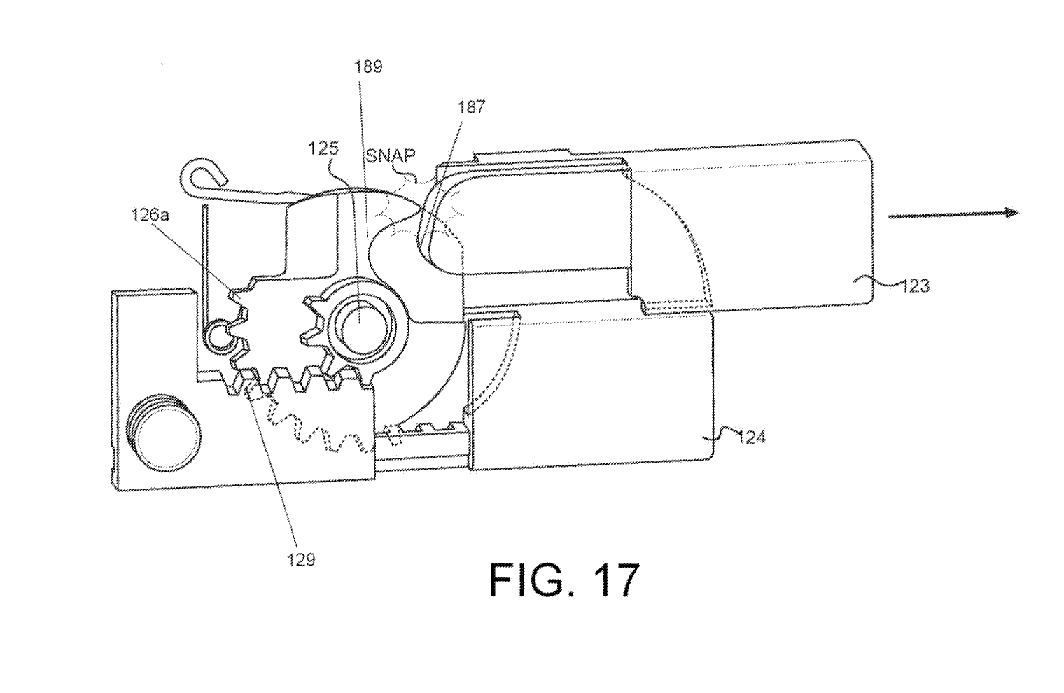

FIG. 17 is a side perspective of the pushbutton mechanism. When the pushbutton 123 is released, the tip 184 of extraction pushbutton 123 protrudes slightly from the front surface of the chassis 70 and may be pulled outward of the pushbutton mechanism 172 until the rounded end 187 of a semi-rigid arm [no number] of pushbutton 123 snaps over a recessed cam surface 189 on the gear portion 125. The extraction button 123 may then be pushed into the pushbutton mechanism in order to extract the electronic module.

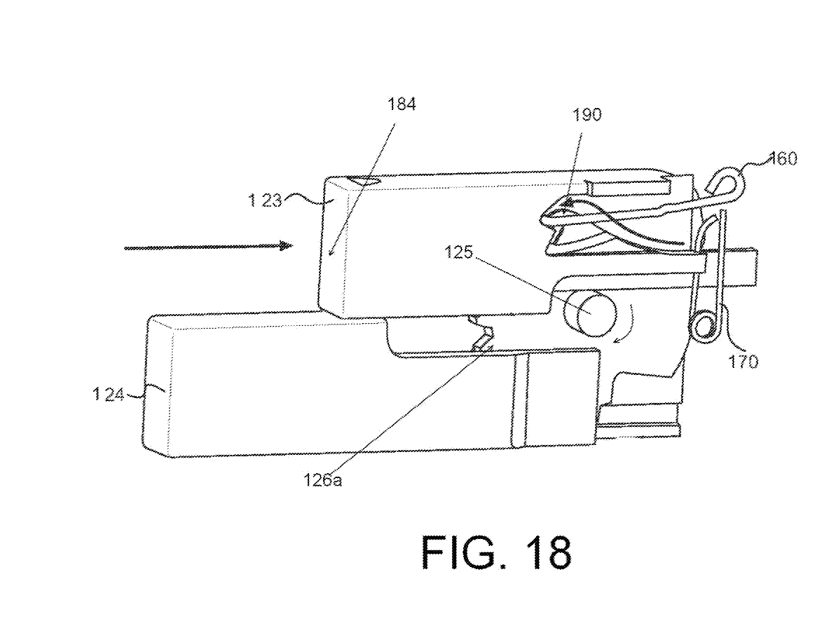

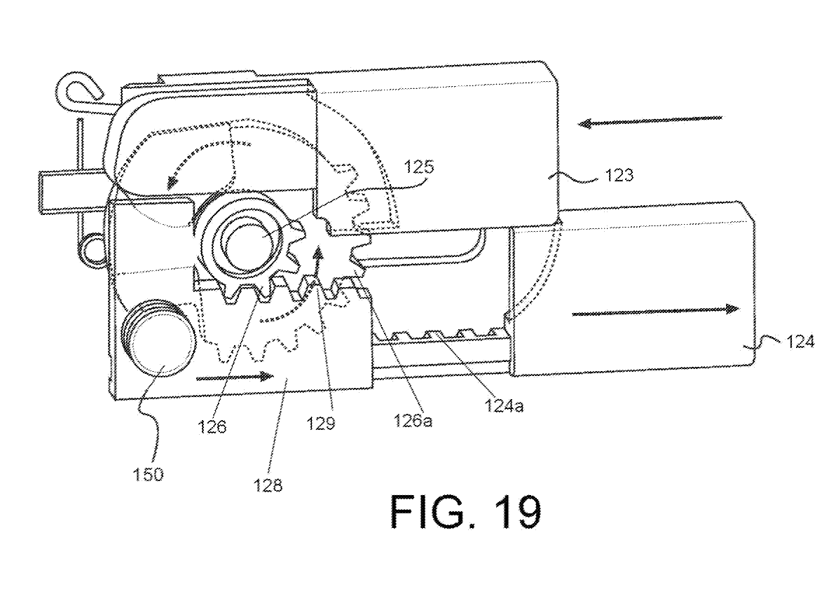

FIG. 18 is a side perspective view of the pushbutton mechanism where extraction button 123 is actuated. FIG. 19 is a side perspective view of the pushbutton mechanism where extraction button 123 is actuated. During actuation, the rounded end 187 of extraction button 123 pushes against the cam surface 189 of gear portion 125 (FIG. 17), causing rack portion 124a to engage pinion portion 126a as pinion portion 126a rotates in the direction of the arrow thereby moving the receiving section, and thus, the receiving member 150 outward. As the receiving member 150 moves outward from chassis 70, the electronic connectors 5, 6 disengage from the corresponding connectors 3, 4 on the backplane 74 of the chassis (FIG. 11) and the electronic module latched to receiving member 150, moves outward from the chassis.

Release of the latching member 16 may be effectuated as discussed with regard to FIG. 10.

The insertion button 124 may operate similar to the operation described in FIGS. 1-10 of insertion button 23.

It may be appreciated that the embodiments described herein are provided as examples to explain the pushbutton mechanism for inserting and extracting electronic modules. The pushbutton mechanism may be implemented in alternative configurations. For example the insertion button and the extraction button may be switched where the insertion button is configured on top of the extraction button.

Alternatively, the ratio of the size of the pinions may be adjusted in order to provide a lesser, or greater, mechanical advantage.

Insertion button, extraction button, gear portion, and receiving section may be made of plastic, cast metal, machined metal, or sheet metal. Springs and track follower would be made of any rigid spring material such as piano wire, spring steel, hard stainless steel. Chassis parts might be made of formed sheet metal or plastic.

I claim:

1. An apparatus, comprising:
a first pushbutton member;
a receiving member movable by the pushbutton member; and
a latching member affixed to an electronic module and latchable to the receiving member, wherein when the latching member is latched to the receiving member, the electronic module is movable via the receiving member.

2. The apparatus of claim 1, wherein the latching member is fixed at a pivot point to the electronic module, the latching member to pivot about the pivot point.

3. The apparatus of claim 2, further comprising:
a displacement member to engage the latching member to pivot the latching member about the pivot point to enable the latching member to latch to the receiving member.

4. The apparatus of claim 1, wherein pushbutton member and the receiving member are affixed to a chassis.

5. The apparatus of claim 1, further comprising:
a first pinion to engage with a rack portion of the pushbutton member;
a second pinion co-located on an axis of rotation of the first pinion; and
a receiving section having the receiving member protruding therefrom and a rack portion to engage with the second pinion,
wherein the receiving section is movable via the rack of the receiving section, and the first and second pinions by operation of the pushbutton member.

6. The apparatus of claim 1, wherein the electronic module has mounted thereon an electronic connector to engage with a complementary electronic connector positioned inside a chassis.

7. The apparatus of claim 6, further comprising:
a second pushbutton member, wherein when the second pushbutton member is pushed, separately from the first pushbutton member, the apparatus inserts the electronic module into a chassis where the electronic connector engages with the complementary electronic connector positioned inside the chassis;
wherein the first pushbutton member, when pushed separately from the second pushbutton member, disengages the electronic connector from the complementary electronic connector inside the chassis and extracts the electronic module from the chassis.

8. The apparatus of claim 1, further comprising:
a first plate covering a first side of the pushbutton member and the receiving member, the first plate having disposed thereon a displacement member to engage the latching member to pivot the latching member about the pivot point to enable the latching member to latch to the receiving member; and
a second plate covering a second side opposite to the first side of the pushbutton member and the receiving member, the second plate being affixed to a side wall of a chassis.

9. An apparatus, comprising:
a first pushbutton member;
a second pushbutton member movable in a direction opposite to a direction of movement of the first pushbutton member; and
a receiving section having a receiving member protruding therefrom, the receiving member movable by the first and second pushbutton member, the receiving member to receive a latching member affixed to an electronic module and latchable to the receiving member, wherein when the latching member is latched to the receiving member, the electronic module is movable via the receiving member.

10. The apparatus of claim 9, wherein the first pushbutton member has a rack portion; wherein the second pushbutton member has a rack portion; and wherein the receiving section has a rack portion; the apparatus further comprising:
a first pinion to engage with the rack portion of the first pushbutton member and the rack portion of the second pushbutton member; and
a second pinion, co-located on an axis of rotation of the first pinion, to engage with the rack portion of the receiving section;
wherein the receiving member is movable by the first and second pushbutton member via the first pinion engaged with the rack portion of one of the first and second pushbutton members and the second pinion engaged with the rack member of the receiving section.

11. The apparatus of claim 9, further comprising:
a first plate covering a first side of the first and second pushbutton members and a first side of the receiving section, the first plate having disposed thereon a displacement member to engage the latching member to pivot the latching member to enable the latching member to latch to the receiving member; and
a second plate covering a second side opposite to the first side of the first and second pushbutton members and the receiving member, the second plate being affixed to a side wall of a chassis.

12. The apparatus of claim 11, wherein
the first plate includes a hole through which the receiving member protrudes, the hole to provide a guide for the receiving member as the receiving member moves via the first and second pushbutton members.

13. The apparatus of claim 9, wherein the electronic module has mounted thereon an electronic connector to engage with a complementary electronic connector positioned inside a chassis.

14. The apparatus of claim 13, wherein
when the second pushbutton member is pushed, the apparatus inserts the electronic module into a chassis where the electronic connector engages with the complementary electronic connector positioned inside the chassis; and
when the first pushbutton member is pushed separately from the second pushbutton member, the electronic connector on the electronic module disengages from the complementary electronic connector inside the chassis and the electronic module is extracted from the chassis.

15. The apparatus of claim 9, wherein the latching member is fixed at a pivot point to the electronic module, the latching member to pivot about the pivot point.

16. An apparatus, comprising:
an electronic module; and
a latching member affixed to the electronic module and pivotable at a pivot point, the latching member to latch to a receiving member,
wherein when the latching member is latched to the receiving member, the electronic module is movable via the receiving member in a direction of movement of the receiving member.

17. The apparatus of claim 16, further comprising:
a displacement member to engage the latching member to pivot the latching member about the pivot point to enable the latching member to latch to the receiving member.

18. The apparatus of claim 16, further comprising:
a pushbutton member, having a rack portion;
a first pinion engageable with the rack portion of the pushbutton member;
a second pinion co-located on an axis of rotation of the first pinion;
a receiving section including a rack portion engageable with the second pinion, the receiving section further including the receiving member protruding from the receiving section,
wherein the receiving member is movable via the rack portion of the pushbutton member acting on the pinion acting on the rack portion of the receiving section.

19. The apparatus of claim 18, further comprising:
a track follower engageable with the pushbutton member; and
a spring exerting a force on the pushbutton member, wherein when the pushbutton member is actuated, the track follower releases the pushbutton member and the force exerted on the pushbutton member acts on the pushbutton member where the pushbutton member protrudes from a front surface of the apparatus.

20. The apparatus of claim 19, wherein the pushbutton member and the receiving member are affixed to a chassis and wherein the electronic module has mounted thereon an electronic connector to engage with a complementary electronic connector positioned on a backplane inside the chassis.
